(19) United States
(12) Patent Application Publication
(10) Pub. No.: US 2019/0129095 A1
(43) Pub. Date: May 2, 2019

(54) IMPLANTED BACK ABSORBER

(71) Applicant: Intel Corporation, Santa Clara, CA (US)

(72) Inventors: Kimchau Nhu Nguyen, Los Gatos, CA (US); George A. Ghiurcan, Corrales, NM (US); Yoel Chetrit, Kfar Ben Nun (IL); Jeffrey B. Driscoll, San Jose, CA (US); Richard Jones, San Mateo, CA (US); Harel Frish, Albuquerque, NM (US); Reece A. Defrees, Rio Rancho, NM (US); Wenhua Lin, Fremont, CA (US); Jung S. Park, San Jose, CA (US)

(73) Assignee: Intel Corporation, Santa Clara, CA (US)

(21) Appl. No.: 16/216,976

(22) Filed: Dec. 11, 2018

(51) Int. Cl. G02B 6/122; G02B 6/24; H01S 5/026

(52) U.S. Cl. CPC G02B 6/1225; G02B 2006/12061; H01S 5/026; G02B 6/243

(57) ABSTRACT

Embodiments may relate to a silicon photonic chip, and particularly a back absorber within the silicon photonic chip. The back absorber may include a substrate material with a slab portion that includes a doped portion of the substrate material. The back absorber may be positioned at the backside of a laser that is configured to project light along a waveguide of the silicon photonic chip. Other embodiments may be described or claimed.

### BACKGROUND

Silicon photonics integrated circuits, including transmitters, receivers, or sensors may incorporate integrated lasers. The lasers may be fabricated by bonding III-V material on a silicon (Si) substrate.

### BRIEF DESCRIPTION OF THE DRAWINGS

FIG. 1 depicts an example silicon photonic chip that includes an optical laser with an implanted back absorber, in accordance with various embodiments.

FIG. 2 depicts an example cross-sectional view of the implanted back absorber of FIG. 1, in accordance with various embodiments.

FIG. 3 depicts an example cross-sectional view of the silicon photonic chip of FIG. 1, in accordance with various embodiments.

FIG. 4 depicts an example simulated waveguide cross section with a doping profile of an implanted back absorber, in accordance with various embodiments.

FIG. 5 depicts a first part of an example technique which may be used for generating an implanted back absorber, in accordance with various embodiments.

FIG. 6 depicts a second part of an example technique which may be used for generating an implanted back absorber, in accordance with various embodiments.

FIG. 7 depicts a simplified flowchart related to the generation of an implanted back absorber, in accordance with various embodiments.

FIG. 8 illustrates an example device that may use various embodiments herein, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature formed, deposited, or otherwise disposed on a second feature,” may mean that the first feature is formed, deposited, or disposed over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As noted above, silicon photonic chips may include a laser that is based on bonding III-V material to a Si substrate. Generally, these lasers may benefit from the inclusion of a low back reflection optical absorber in the bonding region (that is, at or close to the region where the III-V material is bonded to the Si substrate). This absorber may be used to absorb light emitted from the backside of the laser. Generally, if this light is not absorbed, then reflection of the light may result in increased relative intensity noise (RIN) of the laser. In some cases, the reflection may result in coherence collapse which may cause failure of the laser operation in the optical link.

Additionally, the III-V bonding process used to fabricate integrated lasers on Si may be sensitive to roughness on the surface of the Si. Specifically, roughness of the surface may lead to bonding yield loss and material delamination. In other words, the III-V material may not bond appropriately with the Si, or it may subsequently delaminate.

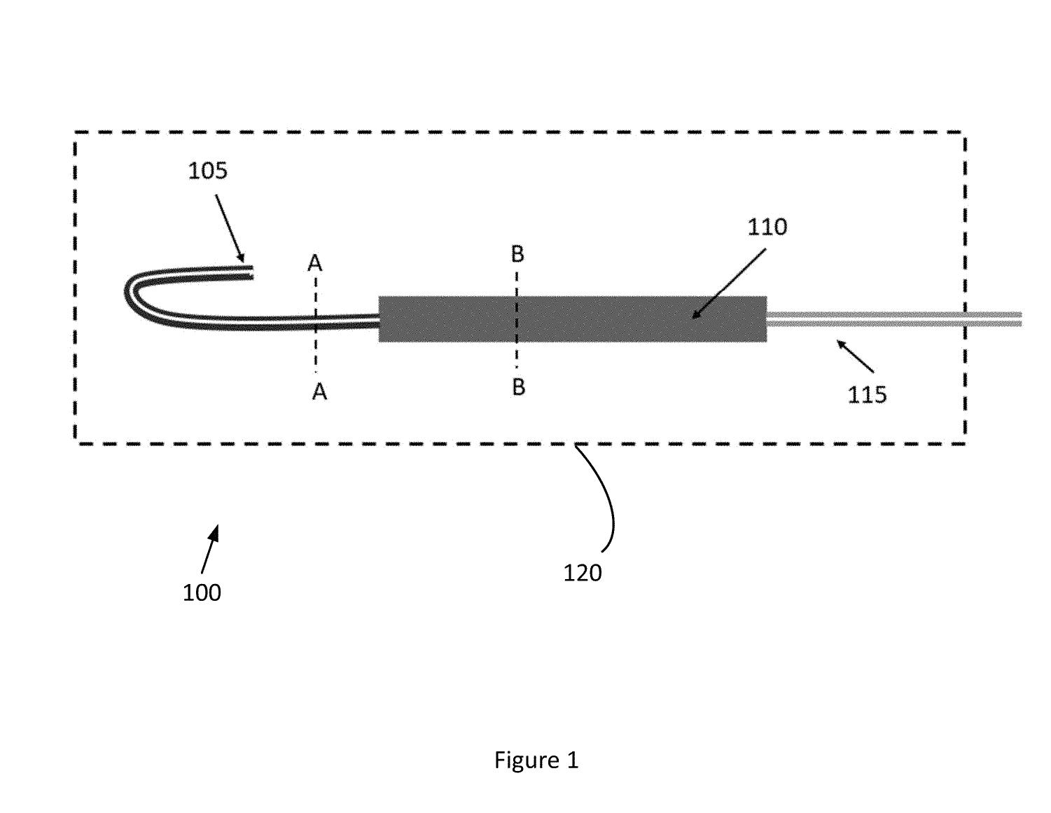

Embodiments herein may relate to a back absorber for a silicon photonic laser. The back absorber may include implanted dopants in the slab portion of a waveguide. The dopants may be in a portion of the waveguide behind the laser, and may absorb the light emitted from the backside of the laser. Additionally, the bonding surface of the back absorber may be protected during implantation of the dopants to avoid roughening the surface of the back absorber. Use of such a back absorber may reduce cost of the silicon photonic chip, because it may reduce the use of relatively costly III-V materials. Additionally, protection of the rib of the back absorber during implantation of the dopant in the slab of the waveguide may improve the overall manufacturing yield by reducing the surface roughness of the top of the waveguide, and thereby reducing the delamination of bonding failures of the III-V material. Generally, the back absorbers herein may have a back reflection of less than approximately −30 decibels (dB), or less than 0.01% back reflection, as measured when used with a waveguide that has sufficient absorption loss, and the length of the waveguide is sufficient to suppress back reflection from the termination of the back absorber waveguide. In various embodiments, the back absorber waveguide may be curved as depicted in FIG. 1, while in other embodiments the back absorber waveguide may be straight or have some other shape.

FIG. 1 depicts an example silicon photonic chip 100 that includes an optical laser with an implanted back absorber, in accordance with various embodiments. Generally, the chip 100 may be a portion of a silicon photonic integrated circuit (IC) or a standalone chip. In some embodiments, the chip 100 may be or may include one or more of a silicon photonic transmitter, receiver, or sensor.

In embodiments, the silicon photonic chip 100 may include a laser 110. The laser 110 may be configured to transmit an optical signal along a waveguide 115. Generally, the laser 110 may include active light emitting material coupled with the waveguide 115. The active light emitting material may be or include III-V compounds. Specifically, the active light emitting material may include a combination of elements in group III of the periodic table (e.g., aluminum, gallium, indium, etc.) and elements in group V of the periodic table (e.g., phosphorous, arsenic, antimony, etc.) For example, the III-V compounds may include gallium nitride (GaN), gallium arsenide (GaAs), indium phosphide (InP), aluminum arsenide (AlAs), various combinations of the elements or compounds (e.g., InGaAsP, InAlGaAs, etc.), or some other III-V compound. In some embodiments, the active light emitting material may include glass, ceramic, or some other material. In some embodiments the active light emitting material may include various layers of the above compounds or some other type of gain material. The waveguide 115 may include, for example Si, InP or any semiconductor that can be doped to induce free carriers. It will be understood that the above-described example elements are intended as a non-exhaustive grouping of examples, and other embodiments may include additional or alternative materials, compounds, or elements to those listed above as will be understood as appropriate in the art.

The silicon photonic chip 100 may further include a back absorber 105. As shown in FIG. 1, the back absorber 105 may be positioned at a part of the laser 110 opposite the portion where the optical signal is to be projected along the waveguide 115. Generally, and as will be described in further detail below, the back absorber 105 may be generally formed of the same material as the waveguide 115. Specifically, the back absorber 105 may include silicon. However, as will be described in further detail below, the back absorber 105 may additionally include one or more doped portions which may absorb light emitted from the backside of the laser 110.

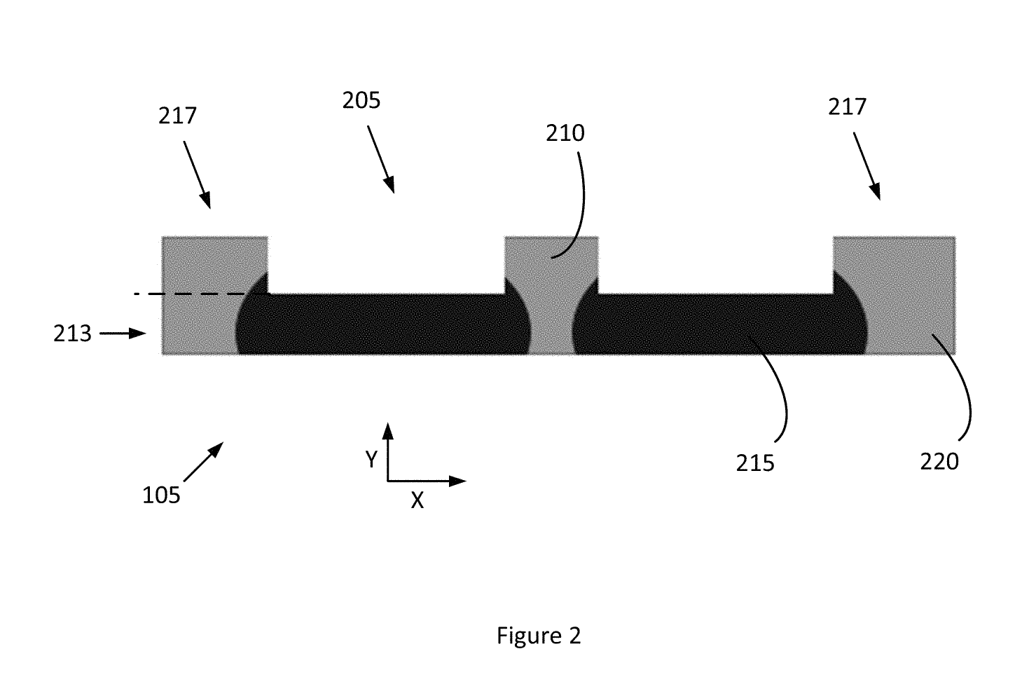

FIG. 2 depicts an example cross-sectional view of the back absorber 105 of FIG. 1, in accordance with various embodiments. Specifically, FIG. 2 may depict a view of the back absorber 105 taken along line A-A of FIG. 1.

As can be seen the back absorber 105 may include a substrate material 220. As noted above, the substrate material 220 may be silicon or some other material such as InP. The substrate material 220 may have one or more trenches 205 therein. The trenches 205 may be formed by, for example, mechanical etching, optical etching, chemical etching, drilling, or some other technique.

Generally, as depicted in FIG. 2, trenches 205 may define various portions of the back absorber 105. Specifically, the trenches 205 may expose the slab portion 213 of the back absorber. Similarly, the trenches 205 may define a rib portion 210 and side portions 217. As can be seen, the rib portion 210 may generally protrude above the slab portion 213. Although these elements of the back absorber 105 are discussed herein as different elements and numbered differently, it will be understood that the rib portion 210, the side portions 217, and the slab portion 213 are generally unitary elements of the back absorber 105, and are discussed herein as different elements for the sake of discussion only.

In embodiments, the back absorber 105 may have an overall width, as measured along the X-axis, between approximately 1 micrometer (micron or μm) and approximately 150 microns. Similarly, the trenches 205 may have a width between approximately 1 micron and approximately 50 microns. Similarly, the rib portion 210 may have a width between approximately 0.1 microns and approximately 50 microns. In some embodiments, the back absorber 105 may have an overall height, as measured along the Y-axis, between approximately 0.1 microns and approximately 10 microns. The trenches 205 may have a depth, as measured along the Y-axis, between approximately 0.1 microns and approximately 10 microns. It will be understood that these values are intended herein as examples, and other embodiments may have heights, widths, or depths that are greater or smaller than those listed based on, for example, the design parameters of the back absorber 105, the design parameters of the silicon photonic chip 100, the materials used, etc.

In embodiments, the slab portion 213 may include doped portions 215 generally positioned within the trenches 205. The doped portion 215 may include, for example, concentrations between approximately 1e12 and approximately 1e20 per cubic centimeter (cm⁻³) of a dopant such as boron, phosphorous, arsenic, or gallium in the substrate material 220. However, it will be understood that these ranges are intended only as examples, and other embodiments may have higher or lower dopant concentrations. As can be seen in FIG. 2, in some embodiments the doped portion 215 penetrate through the entire slab 213 of the substrate material 220. However, in other embodiments the doped portion 215 may only partially penetrate through the slab 213. In some embodiments, the doped portion 215 may generally be rounded and at least partially up along the rib portion 210 or along the trenches 205 up the side portions 217 of the substrate material 220. This rounding and partial extension may be due at least in part to the technique by which the dopant is introduced to the substrate material 220. However, in other embodiments the doped portion 215 may not be rounded, or it may not extend at least partially along the rib portion 210 or the side portions 217 of the trenches 205. Generally, the specific shape, size, or location of the doped portion 215 within the slab portion 213 may be altered by altering factors such as the technique by which the dopants are injected into the substrate material 220, the angle of injection, the time frame in which the dopants are injected, etc. Additionally, the shape, size, or location of the doped portion 215 within the slab portion 213 may be based on factors such as design characteristics of a system in which the silicon photonic chip will be used, the type of laser to be used, the wavelength or intensity of the optical beam, etc.

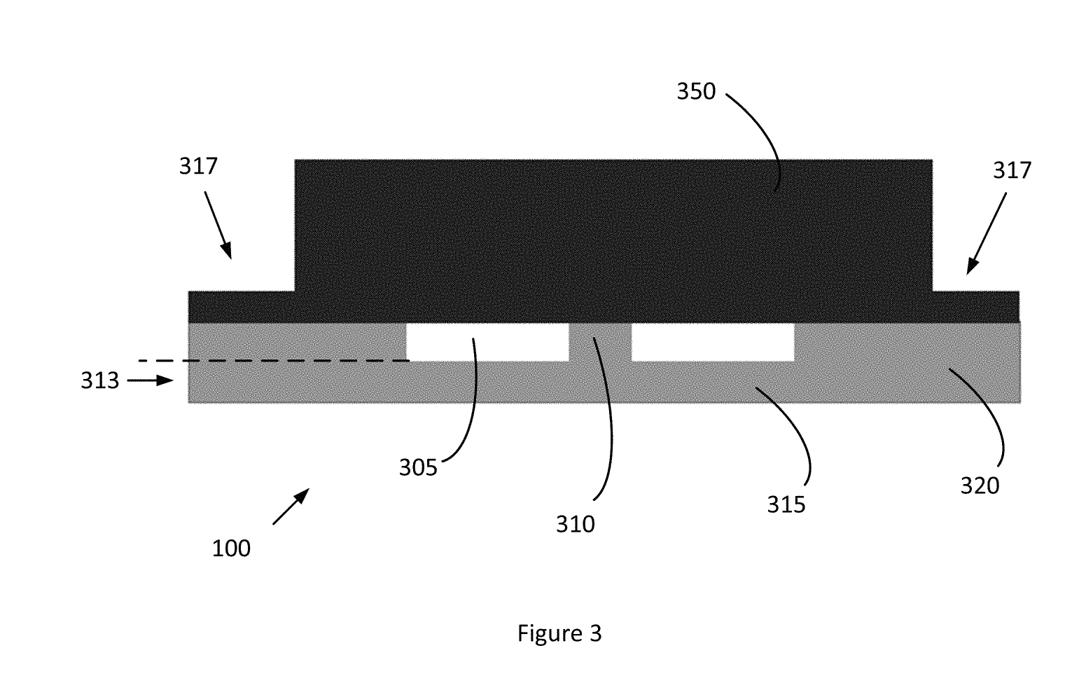

FIG. 3 depicts an example cross-sectional view of the silicon photonic chip 100 of FIG. 1, in accordance with various embodiments. Specifically, FIG. 3 may depict a cross-sectional view along line B-B of FIG. 1.

The silicon phonic chip 100 may include a laser portion 350, which may be similar to laser 110. As discussed above, the laser portion 350 may be formed of a III-V material such as those discussed above, and may be bonded with substrate material 320, which may be similar to substrate material 220. Additionally, as can be seen in FIG. 3, the silicon photonic chip 100 at the cross section portion of line B-B may include several elements similar to those of FIG. 2. Specifically, the silicon photonic chip 100 may include a substrate material 320 with a plurality of trenches 305 therein, which may be similar to substrate material 220 and trenches 205. Similarly to FIG. 2, the substrate material 320 may include a slab portion 313 which is exposed by the trenches 305, a side portions 317, and a rib portion 310, which may be respectively similar to slab portion 213, side portions 217, and rib portion 210. Generally, the portion of the silicon photonic chip 100 depicted at FIG. 3 may have dimensions similar to those of the back absorber in FIG. 2. In other words, the rib portion 310, the substrate material 320, the trenches 305, etc. may have similar heights, widths, or depths to those discussed above with respect to similar elements in FIG. 2.

However, as can be seen in FIG. 3, the slab portion 313 may not include the doped portions 215 depicted in FIG. 2. The laser portion 350 may generate an optical beam within the rib portion 310 and the laser portion 350, and the optical beam may propagate along the rib portion 310 where it may exit the laser 110 into waveguide 115. Generally, it will be understood that the combination of the laser portion 350 and the substrate material 320 may be considered the laser 110 of FIG. 1.

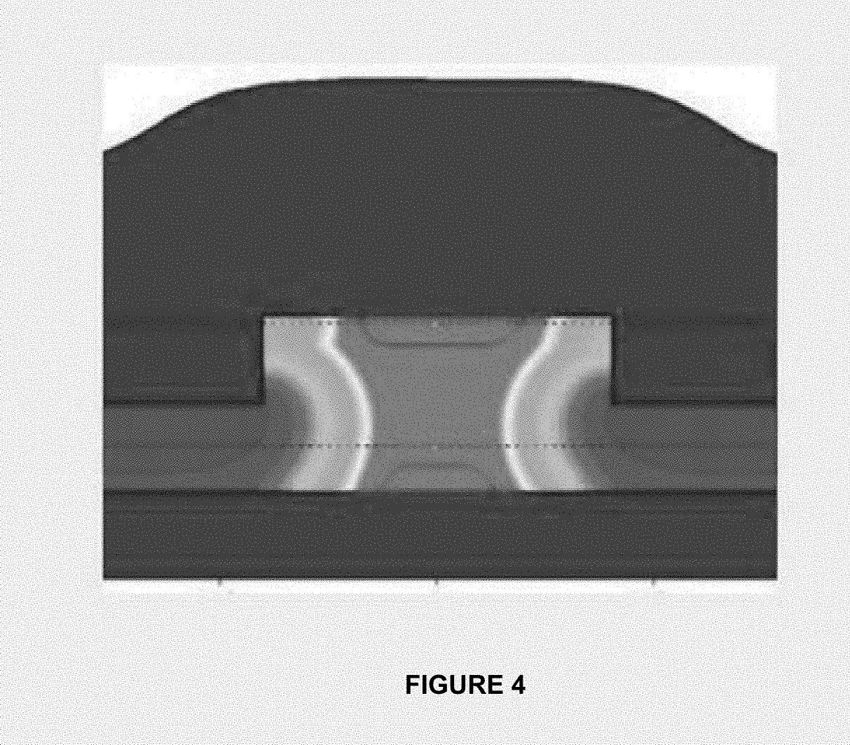

FIG. 4 depicts an example simulated waveguide cross section with a doping profile of an implanted back absorber, in accordance with various embodiments. Specifically, FIG. 4 depicts a simulation for a dopant-implanted back absorber with concentration contours. Generally, higher absorption losses from free carrier absorption may be achievable with narrower waveguide widths. This absorption loss may be achievable because the optical mode of a narrower waveguide may overlap more with the dopants such as doped portion 215. As used herein, waveguide width may refer to the width of the rib portion 210.

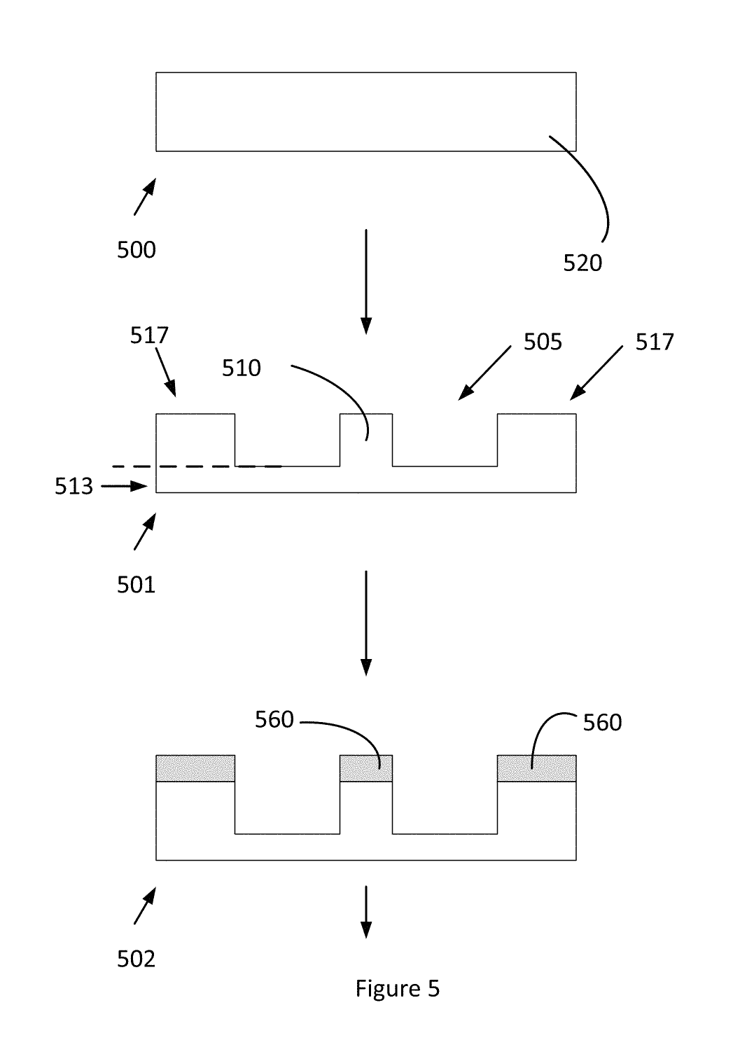

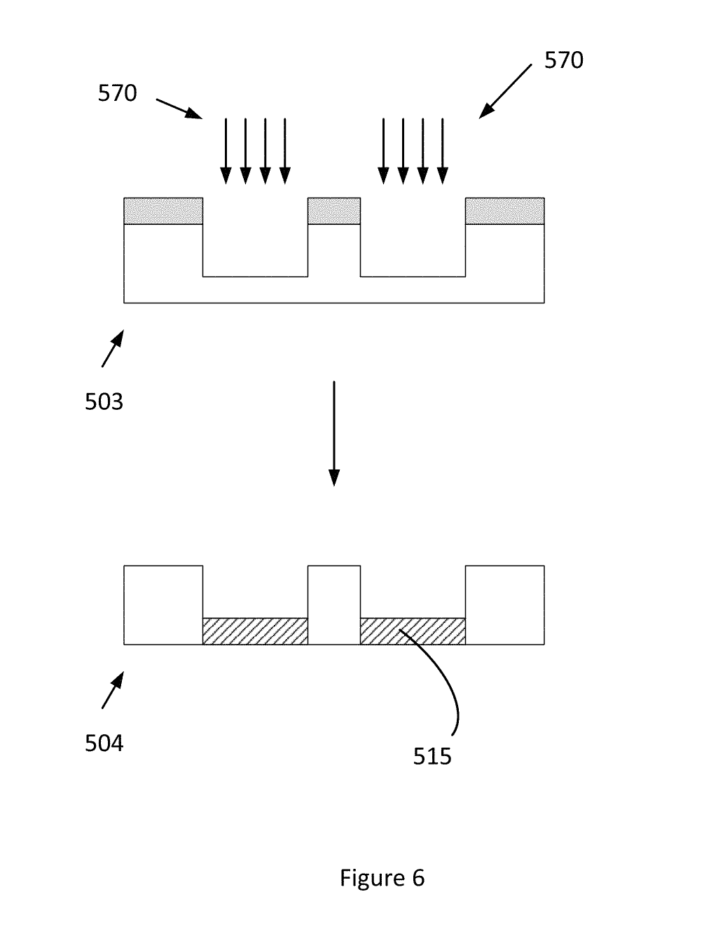

FIGS. 5 and 6 graphically depict a simplified example technique by which a back absorber such as back absorber 105 may be generated. It will be understood that each portion of the technique of FIGS. 5 and 6 may not have every element numbered if the element has been previously numbered. This lack of renumbering is for the sake of clarity of the Figures.

Specifically, at 500, a substrate material 520 may be identified. The substrate material 520 may be similar to substrate material 220.

Next, at 501, one or more trenches 505, which may be similar to trenches 205, may be formed in the substrate material 520. The trenches 505 may expose the slab portion 513, which may be similar to slab portion 213, and define the rib portion 510 and the side portions 517, which may be respectively similar to rib portion 210 and side portions 217.

Next, at 502, a hardmask material 560 may be positioned on the side portions 517 and the rib portion 510. The hardmask material 560 may be, for example, silicon oxide, silicon nitride, polyimide, metals, or some other material that is able to screen dopants. It will be noted in FIG. 5 that the hardmask material 560 is absent from the trenches 505.

Moving to FIG. 6, at 503, the dopant 570 may be implanted in the substrate material 520. Specifically, as shown in FIG. 6, the dopant 570 may be implanted into the slab portion 513 of the substrate material 520 through the trenches 505.

The dopant 570 may, as shown at 504, form one or more doped portions 515, which may be similar to doped portions 215. Generally, it will be understood that although the implantation of the dopant 570 is depicted at 503 as being generally vertical with respect to the Figure and the trench 505, in other embodiments the dopant 570 may be implanted at one or more angles with respect to the trench 505. In other words, the implantation of the dopant 570 may be “slanted” with respect to the Figure. By implanting the dopant in a manner that is at least partially slanted with respect to the Figure, the resultant doped portions 515 may extend at least partially along the sidewalls of the trench 505, for example at least partially into the side portions 517 or the rib portion 510. Specifically, rather than have the doped portion 515 only in the slab portion as depicted at 504, the doped portion 515 may be more similar to doped portion 215 as discussed above.

Additionally, the hardmask material 560 may be removed from the substrate material, re-exposing the rib portion 510 and the side portions 517. The hardmask material 560 may be removed by, for example, chemical etching, optical etching, mechanical etching, etc. Because the hardmask material 560 was present when the dopant was implanted in the slab portion 513, the surface of the rib portion 510 and the side portions 517 where the hardmask material 560 was present may be relatively smooth. For example, they may retain a surface roughness of less than approximately 1 nanometer (nm) root mean square (RMS). This relative smoothness of the surface of the rib portion 510 and the side portions 517 may allow for increased bonding yield of subsequent III-V material to the substrate material 520, if desired.

In general, although the hardmask material 560 is only depicted as positioned on the back absorber, leaving the trenches 505 exposed for the implantation of the dopant, it will be understood that in some embodiments the hardmask material 560 may be on additional portions of the silicon photonic chip. For example, if the back absorber 105 and the waveguide 115 are already present in the silicon photonic chip, then the entirety of the waveguide 115, including trenches such as trenches 305, may be protected by the hardmask material but also not exposed during the implantation process. The hardmask may be removed before coupling additional III-V material 120, then the III-V material 120 is patterned leaving behind 350 and 317, along with the silicon rib and slab waveguide make up the laser 110.

Generally, it will be understood that the various depictions of the silicon photonic chip 100, portions thereof, or the technique depicted in FIGS. 5 and 6 is intended as a simplified example. Additional elements, layers, portions of the technique, etc. may not be depicted for the sake of simplicity of description and reduction of clutter. Other embodiments may have additional components coupled with the silicon photonic chip 100, portions thereof, or elements of FIG. 5 or 6.

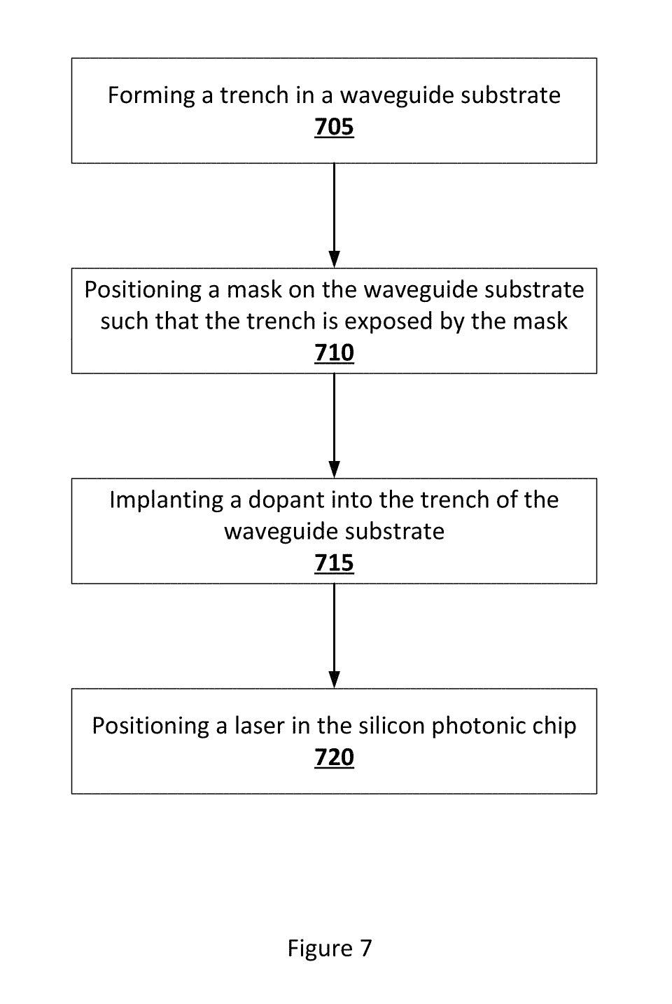

FIG. 7 depicts a simplified flowchart related to the generation of silicon photonic chip such as silicon photonic chip 100, wherein the silicon photonic chip includes an implanted back absorber such as back absorber 105, in accordance with various embodiments. Generally, the technique may include forming trenches in a wave guide substrate at 705. The trench may be, for example, similar to trenches 205 or 505. The waveguide substrate may be, for example, similar to waveguide substrates 220 or 520.

The technique may further include positioning, at 710, a mask on the waveguide substrate such that the trench is exposed by the mask. The mask may be, for example, hardmask 560.

The technique may then include implanting, at 715, a dopant into the trench of the waveguide substrate. For example, the dopant may be the dopant 750 depicted at FIG. 6. Implantation of the dopant may result in the presence of doped portions 215 or 515 in the waveguide substrate 220/520.

Finally, the technique may include positioning, at 720, a laser in the silicon photonic chip. The laser may be, for example, similar to laser 110. More specifically, the laser may be configured to generate and transmit an optical beam along a waveguide such as waveguide 115. The back absorber may be positioned at a side of the laser opposite the side in which the optical beam is intended to propagate. In this manner, the back absorber, and more particularly the doped portions of the back absorber, may absorb light scattered from the back side of the laser.

It will be understood that this technique is intended as one example technique. Other techniques may include additional elements, or the elements of FIG. 7 may be performed in a different order. For example, in some embodiments the laser may be positioned within the silicon photonic waveguide prior to the positioning of the mask at 710 or the implantation of the dopant at 715. Other variations may be present in other embodiments.

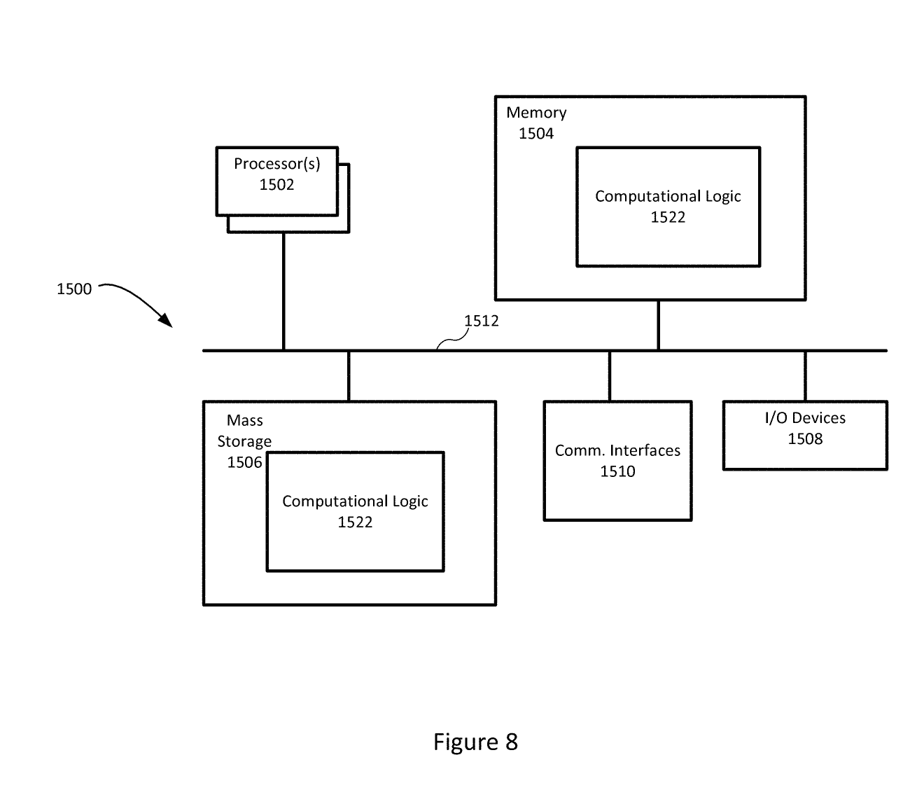

FIG. 8 illustrates an example computing device 1500 suitable for use with silicon photonic chip 100, in accordance with various embodiments. Specifically, in some embodiments, the computing device 1500 may include one or more silicon photonic chips 100 therein.

As shown, computing device 1500 may include one or more processors or processor cores 1502 and system memory 1504. For the purpose of this application, including the claims, the terms “processor” and “processor cores” may be considered synonymous, unless the context clearly requires otherwise. The processor 1502 may include any type of processors, such as a CPU, a microprocessor, and the like. The processor 1502 may be implemented as an IC having multi-cores, e.g., a multi-core microprocessor. The computing device 1500 may include mass storage devices 1506 (such as diskette, hard drive, volatile memory (e.g., DRAM, compact disc read-only memory (CD-ROM), digital versatile disk (DVD), and so forth)). In general, system memory 1504 and/or mass storage devices 1506 may be temporal and/or persistent storage of any type, including, but not limited to, volatile and non-volatile memory, optical, magnetic, and/or solid state mass storage, and so forth. Volatile memory may include, but is not limited to, static and/or DRAM. Non-volatile memory may include, but is not limited to, electrically erasable programmable read-only memory, phase change memory, resistive memory, and so forth. In some embodiments, one or both of the system memory 1504 or the mass storage device 1506 may include computational logic 1522, which may be configured to implement or perform, in whole or in part, one or more instructions that may be stored in the system memory 1504 or the mass storage device 1506. In other embodiments, the computational logic 1522 may be configured to perform a memory-related command such as a read or write command on the system memory 1504 or the mass storage device 1506.

The computing device 1500 may further include input/output (I/O) devices 1508 (such as a display (e.g., a touchscreen display), keyboard, cursor control, remote control, gaming controller, image capture device, and so forth) and communication interfaces 1510 (such as network interface cards, modems, infrared receivers, radio receivers (e.g., Bluetooth), and so forth).

The communication interfaces 1510 may include communication chips (not shown) that may be configured to operate the device 1500 in accordance with a Global System for Mobile Communication (GSM), General Packet Radio Service (GPRS), Universal Mobile Telecommunications System (UMTS), High Speed Packet Access (HSPA), Evolved HSPA (E-HSPA), or Long-Term Evolution (LTE) network. The communication chips may also be configured to operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chips may be configured to operate in accordance with Code Division Multiple Access (CDMA), Time Division Multiple Access (TDMA), Digital Enhanced Cordless Telecommunications (DECT), Evolution-Data Optimized (EV-DO), derivatives thereof, as well as any other wireless protocols that are designated as 3G, 4G, 5G, and beyond. The communication interfaces 1510 may operate in accordance with other wireless protocols in other embodiments.

The computing device 1500 may further include or be coupled with a power supply. The power supply may, for example, be a power supply that is internal to the computing device 1500 such as a battery. In other embodiments the power supply may be external to the computing device 1500. For example, the power supply may be an electrical source such as an electrical outlet, an external battery, or some other type of power supply. The power supply may be, for example alternating current (AC), direct current (DC) or some other type of power supply. The power supply may in some embodiments include one or more additional components such as an AC to DC convertor, one or more downconverters, one or more upconverters, transistors, resistors, capacitors, etc. that may be used, for example, to tune or alter the current or voltage of the power supply from one level to another level. In some embodiments the power supply may be configured to provide power to the computing device 1500 or one or more discrete components of the computing device 1500 such as the processor(s) 1502, mass storage 1506, I/O devices 1508, etc.

The above-described computing device 1500 elements may be coupled to each other via system bus 1512, which may represent one or more buses. In the case of multiple buses, they may be bridged by one or more bus bridges (not shown). Each of these elements may perform its conventional functions known in the art. The various elements may be implemented by assembler instructions supported by processor(s) 1502 or high-level languages that may be compiled into such instructions.

The permanent copy of the programming instructions may be placed into mass storage devices 1506 in the factory, or in the field, through, for example, a distribution medium (not shown), such as a compact disc (CD), or through communication interface 1510 (from a distribution server (not shown)). That is, one or more distribution media having an implementation of the agent program may be employed to distribute the agent and to program various computing devices.

The number, capability, and/or capacity of the elements 1508, 1510, 1512 may vary, depending on whether computing device 1500 is used as a stationary computing device, such as a set-top box or desktop computer, or a mobile computing device, such as a tablet computing device, laptop computer, game console, or smartphone. Their constitutions are otherwise known, and accordingly will not be further described.

In various implementations, the computing device 1500 may comprise one or more components of a data center, a laptop, a netbook, a notebook, an ultrabook, a smartphone, a tablet, a personal digital assistant (PDA), an ultra mobile PC, a mobile phone, or a digital camera. In further implementations, the computing device 1500 may be any other electronic device that processes data.

Generally, one or more components of the computing device 1500 such as the processor 1502, communication interfaces 1510, etc. may include the silicon photonic chip 100. The silicon photonic chip 100 may be used to allow communication between separate portions of, for example, the processor 1502, or to allow the element to communicate with another element of the computing device 1500 via the system bus 1512.

### Examples of Various Embodiments

Example 1 includes a silicon photonic chip comprising: a back absorber that includes a substrate material with a rib portion and a slab portion, and wherein the rib portion and the slab portion define a trench such that the slab portion is exposed within the trench, and wherein the slab portion includes a doped portion of the substrate material within the trench; and a laser positioned within the silicon photonic chip, wherein the laser has a first side and a second side opposite the first side, wherein the back absorber is adjacent to the second side of the laser and wherein the laser is to project an optical beam along a waveguide at a first side of the laser.

Example 2 includes the silicon photonic chip of example 1, wherein the substrate material is silicon.

Example 3 includes the silicon photonic chip of example 1, wherein the doped portion of the substrate material includes implanted phosphorous or boron.

Example 4 includes the silicon photonic chip of example 1, wherein the doped portion of the substrate material is capable of absorbing light emitted from the laser

Example 5 includes the silicon photonic chip of any of examples 1-4, wherein the laser includes a III-V layer coupled with the waveguide.

Example 6 includes the silicon photonic chip of example 5, wherein the III-V layer includes indium phosphide.

Example 7 includes the silicon photonic chip of any of examples 1-4, wherein the back absorber is directly adjacent to the second side of the laser.

Example 8 includes a method of forming a silicon photonic chip, the method comprising: forming a trench in a waveguide substrate; positioning a mask on the waveguide substrate such that the trench is exposed by the mask; implanting a dopant into the trench of the waveguide substrate; and positioning a laser in the silicon photonic chip, wherein the laser has a first side and a second side opposite the first side, wherein the second side of the laser is adjacent to the trench, and wherein the laser is to project an optical beam from the first side of the laser.

Example 9 includes the method of example 8, further comprising removing the mask subsequent to the implanting the dopant.

Example 10 includes the method of example 8, wherein the waveguide substrate includes silicon.

Example 11 includes the method of example 8, wherein the dopant includes phosphorous or boron.

Example 12 includes the method of example 8, wherein the dopant is capable of absorbing light emitted from the laser.

Example 13 includes the method of any of examples 8-12, wherein the laser includes a III-V layer coupled with the waveguide.

Example 14 includes the method of example 13, wherein the III-V layer includes indium phosphide.

Example 15 includes an electronic device comprising: a first component; a second component; a waveguide that communicatively couples the first component and the second component; and a silicon photonic chip coupled with the waveguide, wherein the silicon photonic chip includes: a silicon substrate with a trench positioned therein, wherein the silicon substrate includes a doped portion of the silicon substrate; and a laser positioned within the substrate and adjacent to the trench, wherein the laser is to generate an optical beam along the waveguide in a direction away from the trench.

Example 16 includes the electronic device of example 15, wherein the doped portion of the silicon substrate includes phosphorous or boron.

Example 17 includes the electronic device of example 15, wherein the doped portion of the silicon substrate is capable of absorbing light transmitted from the laser

Example 18 includes the electronic device of any of examples 15-17, wherein the laser includes a III-V layer coupled with the waveguide.

Example 19 includes the electronic device of example 18, wherein the III-V layer includes indium phosphide.

Example 20 includes the electronic device of any of examples 15-17, wherein the trench is directly adjacent to the laser.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A silicon photonic chip comprising:
a back absorber that includes a substrate material with a rib portion and a slab portion, and wherein the rib portion and the slab portion define a trench such that the slab portion is exposed within the trench, and wherein the slab portion includes a doped portion of the substrate material within the trench; and
a laser positioned within the silicon photonic chip, wherein the laser has a first side and a second side opposite the first side, wherein the back absorber is adjacent to the second side of the laser and wherein the laser is to project an optical beam along a waveguide at a first side of the laser.

2. The silicon photonic chip of claim 1, wherein the substrate material is silicon.

3. The silicon photonic chip of claim 1, wherein the doped portion of the substrate material includes implanted phosphorous or boron.

4. The silicon photonic chip of claim 1, wherein the doped portion of the substrate material is capable of absorbing light emitted from the laser.

5. The silicon photonic chip of claim 1, wherein the laser includes a III-V layer coupled with the waveguide.

6. The silicon photonic chip of claim 5, wherein the III-V layer includes indium phosphide.

7. The silicon photonic chip of claim 1, wherein the back absorber is directly adjacent to the second side of the laser.

8. A method of forming a silicon photonic chip, the method comprising:
forming a trench in a waveguide substrate;
positioning a mask on the waveguide substrate such that the trench is exposed by the mask;
implanting a dopant into the trench of the waveguide substrate; and
positioning a laser in the silicon photonic chip, wherein the laser has a first side and a second side opposite the first side, wherein the second side of the laser is adjacent to the trench, and wherein the laser is to project an optical beam from the first side of the laser.

9. The method of claim 8, further comprising removing the mask subsequent to the implanting the dopant.

10. The method of claim 8, wherein the waveguide substrate includes silicon.

11. The method of claim 8, wherein the dopant includes phosphorous or boron.

12. The method of claim 8, wherein the dopant is capable of absorbing light emitted from the laser.

13. The method of claim 8, wherein the laser includes a III-V layer coupled with the waveguide substrate.

14. The method of claim 13, wherein the III-V layer includes indium phosphide.

15. An electronic device comprising:
a first component;
a second component;
a waveguide that communicatively couples the first component and the second component; and
a silicon photonic chip coupled with the waveguide, wherein the silicon photonic chip includes:
a silicon substrate with a trench positioned therein, wherein the silicon substrate includes a doped portion of the silicon substrate; and
a laser positioned within the silicon substrate and adjacent to the trench, wherein the laser is to generate an optical beam along the waveguide in a direction away from the trench.

16. The electronic device of claim 15, wherein the doped portion of the silicon substrate includes phosphorous or boron.

17. The electronic device of claim 15, wherein the doped portion of the silicon substrate is capable of absorbing light transmitted from the laser.

18. The electronic device of claim 15, wherein the laser includes a III-V layer coupled with the waveguide.

19. The electronic device of claim 18, wherein the III-V layer includes indium phosphide.

20. The electronic device of claim 15, wherein the trench is directly adjacent to the laser.
